(19) United States
(12) Patent Application Publication
(10) Pub. No.: US 2022/0115405 A1
(43) Pub. Date: Apr. 14, 2022

(54) HETEROGENEOUS HEIGHT LOGIC CELL ARCHITECTURE

(71) Applicant: QUALCOMM Incorporated, San Diego, CA (US)

(72) Inventors: Hyeokjin LIM, San Diego, CA (US); Venugopal BOYNAPALLI, San Diego, CA (US); Foua VANG, Sacramento, CA (US); Seung Hyuk KANG, San Diego, CA (US)

(21) Appl. No.: 17/065,746

(22) Filed: Oct. 8, 2020

(51) Int. Cl. H01L 27/118

(52) U.S. Cl. CPC H01L 27/11807; H01L 2027/11881; H01L 2027/11875

(57) ABSTRACT

A MOS IC includes first and second sets of adjacent transistor logic, each of which include collinear gate interconnects extending in a first direction with the same gate pitch. The first set of transistor logic has a first cell height h₁ and a first number of Mₓ layer tracks that extend unidirectionally in a second direction orthogonal to the first direction. The second set of transistor logic has a second cell height h₂ and a second number of Mₓ layer tracks that extend unidirectionally in the second direction, where h₂>h₁ and the second number of Mₓ layer tracks is greater than the first number of Mₓ layer tracks. At least one of a height ratio h_{R}=h₂/h₁ is a non-integer value or a subset of the first set of transistor logic and a subset of the second set of transistor logic are within one logic cell.

### BACKGROUND

### Field

The present disclosure relates generally to a standard/logic cell architecture, and more particularly, to a heterogeneous height standard/logic cell architecture.

### Background

A standard cell device is an integrated circuit (IC) that implements digital logic. Such standard cell device may be reused multiple times within an application-specific IC (ASIC). An ASIC, such as a system-on-a-chip (SoC) device, may contain thousands to millions of standard cell devices. A typical IC includes a stack of sequentially formed layers. Each layer may be stacked or overlaid on a prior layer and patterned to form the shapes that define transistors (e.g., field effect transistors (FETs), fin FETs (FinFETs), gate-all-around (GAA) FETs (GAAFETs), and/or other multigate FETs) and connect the transistors into circuits.

A taller standard cell architecture for tall standard cells may provide higher performance than a shorter standard cell architecture for short standard cells, whereas a shorter standard cell architecture for short standard cells may provide better area efficiency than a taller standard cell architecture for tall standard cells. Both short and tall standard cell architectures may be utilized separately to achieve both higher performance or area efficiency. There is currently a need for a heterogeneous height standard cell architecture for utilizing both short and tall standard cells.

### SUMMARY

In an aspect of the disclosure, a metal oxide semiconductor (MOS) IC includes a first set of transistor logic. The first set of transistor logic has a first plurality of gate interconnects extending in a first direction. The first plurality of gate interconnects has a gate pitch. The first set of transistor logic has one or more pairs of power rails providing a power supply voltage and a ground voltage to logic between each corresponding pair of power rails. The first set of transistor logic has a first cell height h₁ and has a first number of metal x (Mₓ) layer tracks that extend unidirectionally in a second direction between each pair of power rails. The second direction is orthogonal to the first direction. The MOS IC further includes a second set of transistor logic. The second set of transistor logic is located adjacent in the first direction to the first set of transistor logic. The second set of transistor logic has a second plurality of gate interconnects extending in the first direction. The second plurality of gate interconnects has the same gate pitch as the first plurality of gate interconnects and each is collinear with a respective one of the first plurality of gate interconnects. The second set of transistor logic has one or more pairs of power rails providing the power supply voltage and the ground voltage to logic between each corresponding pair of power rails. The second set of transistor logic has a second cell height h₂ and has a second number of Mₓ layer tracks that extend unidirectionally in the second direction between each pair of power rails. The second cell height h₂ is greater than the first cell height h₁. The second number of Mₓ layer tracks is greater than the first number of Mₓ layer tracks. At least one of a height ratio h_{R}=h₂/h₁ is a non-integer value or a subset of the first set of transistor logic and a subset of the second set of transistor logic are within one logic cell.

### BRIEF DESCRIPTION OF THE DRAWINGS

FIG. 1 is a first diagram illustrating a side view of various layers within a standard cell and IC.

FIG. 2 is a second diagram illustrating a side view of various layers within a standard cell and IC.

FIG. 3 is a first diagram conceptually illustrating a top view of a heterogeneous height logic cell architecture.

FIG. 4 is a second diagram conceptually illustrating a top view of the heterogeneous height logic cell architecture.

FIG. 5 is a third diagram conceptually illustrating a top view of the heterogeneous height logic cell architecture.

FIG. 6 is a fourth diagram conceptually illustrating a top view of the heterogeneous height logic cell architecture.

FIG. 7 are a set of diagrams conceptually illustrating top views of different configurations of the heterogeneous height logic cell architecture.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. Apparatuses and methods will be described in the following detailed description and may be illustrated in the accompanying drawings by various blocks, modules, components, circuits, steps, processes, algorithms, elements, etc.

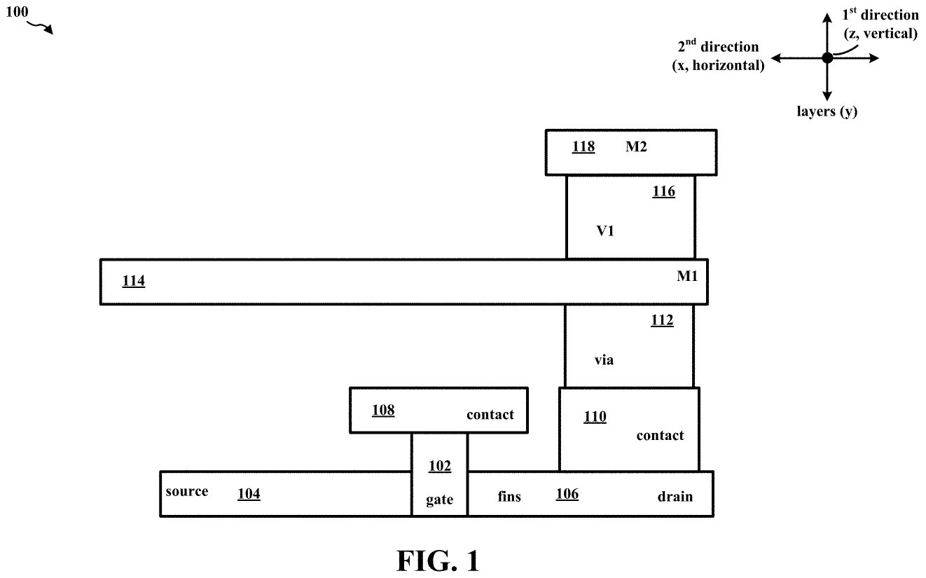

FIG. 1 is a first diagram 100 illustrating a side view of various layers within a standard cell of an IC. The various layers change in the y direction. As illustrated in FIG. 1, a transistor has a gate 102 (which may be referred to as POLY even though the gate 102 may be formed of metal, polysilicon, or a combination of polysilicon and metal), a source 104, and a drain 106. The source 104 and the drain 106 may be disposed on a silicon substrate and formed by fins. The gate 102 may extend in a first direction (e.g., vertical direction along the z axis coming out of the page), and the fins may extend in a second direction orthogonal to the first direction (e.g., horizontal direction along the x axis). A contact layer interconnect 108 (also referred to as a metal POLY (MP) layer interconnect) may contact the gate 102. A contact layer interconnect 110 (also referred to as a metal diffusion (MD) layer interconnect) may contact the source 104 and/or the drain 106. A via 112 may contact the contact layer interconnect 110. A metal 1 (M1) layer interconnect 114 may contact the via 112. The M1 layer interconnect 114 may extend in the second direction only (i.e., unidirectional in the second direction). A via V1 116 may contact the M1 layer interconnect 114. A metal 2 (M2) layer interconnect 118 may contact the via V1 116. The M2 layer interconnect 118 may extend in the first direction only (i.e., unidirectional in the first direction). The M2 layer is a lowest vertical layer. Specifically, the M2 layer may be unidirectional in the vertical direction, and is the closest vertically unidirectional layer to the silicon substrate. Higher layers include a via layer including vias V2 and a metal 3 (M3) layer including M3 layer interconnects. The M3 layer interconnects may extend in the second direction.

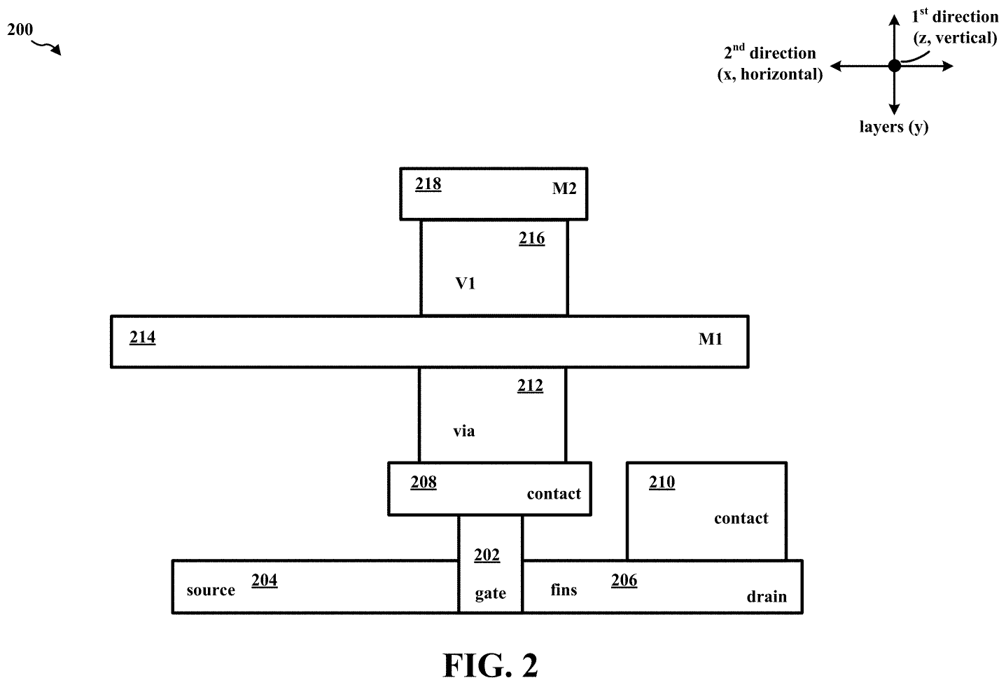

FIG. 2 is a second diagram 200 illustrating a side view of various layers within a standard cell and IC. The various layers change in the y direction. As illustrated in FIG. 2, a transistor has a gate 202, a source 204, and a drain 206. The source 204 and the drain 206 may be formed by fins. The gate 202 may extend in a first direction (e.g., vertical direction along the z axis coming out of the page), and the fins may extend in a second direction orthogonal to the first direction (e.g., horizontal direction along the x axis). A contact layer interconnect 208 may contact the gate 202. A contact layer interconnect 210 may contact the source 204 and/or the drain 206. A via 212 may contact the contact layer interconnect 208. An M1 layer interconnect 214 may contact the via 212. The M1 layer interconnect 214 may extend in the second direction only (i.e., unidirectional in the second direction). A via V1 216 may contact the M1 layer interconnect 214. An M2 layer interconnect 218 may contact the via V1 216. The M2 layer interconnect 218 may extend in the first direction only (i.e., unidirectional in the first direction). The M2 layer is a lowest vertical layer. Specifically, the M2 layer may be unidirectional in the vertical direction, and is the closest vertically unidirectional layer to the silicon substrate. Higher layers include a via layer including vias V2 and an M3 layer including M3 layer interconnects. The M3 layer interconnects may extend in the second direction. While an IC is illustrated with FinFETs in FIGS. 1, 2, the IC may include other multigate FETs, such as double-gate FETs, tri-gate FETs, and/or GAAFETs.

Standard cells are cells that are standardized in a design. The same standard cell may be utilized thousands of times throughout an IC. Herein, standard cells may be referred to as logic cells. A logic cell has a set of inputs and set of outputs, where the inputs/outputs are interconnected through intra-cell routing within the logic cell (rather than inter-cell routing across different logic cells). Such logic cell may be utilized in an IC hundreds to thousands of times, with the same intra-cell routing configuration. The height of a cell is equal to the distance (in the first direction in FIGS. 1, 2) between corresponding pairs of power rails located at the top and bottom portions of the cell, where the top and bottom cell edges extend through the centers of each of the power rails. Cell heights of logic cells may be reduced through technological improvements and design pushes. With respect to technology improvements, cell heights may be reduced by transitioning to a smaller technology process node where the minimum feature size of the process is reduced. Such improvement reduces the cell height of a logic cell without reducing a number of tracks within the logic cell for intra-cell routing (interconnections between transistors in the logic cell so that the logic cell may provide a logic function). With respect to design pushes, cell heights may be reduced through a reduction of the number of tracks within the logic cell for intra-cell routing. Decreasing the cell height of a logic cell through reducing the number of tracks for intra-cell routing (e.g., from 5 to 4, 3, or 2) increases an area efficiency, but may make intra-cell routing difficult, if not impossible. If intra-cell routing is still possible, the track reduction may decrease the performance of the logic cell. As discussed supra, a taller logic cell architecture for tall logic cells may provide higher performance than a shorter logic cell architecture for short logic cells, whereas a shorter logic cell architecture for short logic cells may provide better area efficiency than a taller logic cell architecture for tall logic cells. Both short and tall logic cell architectures with the same technology process node may be utilized to achieve both higher performance and area efficiency. A heterogeneous height logic cell architecture for utilizing both short and tall logic cells is provided infra.

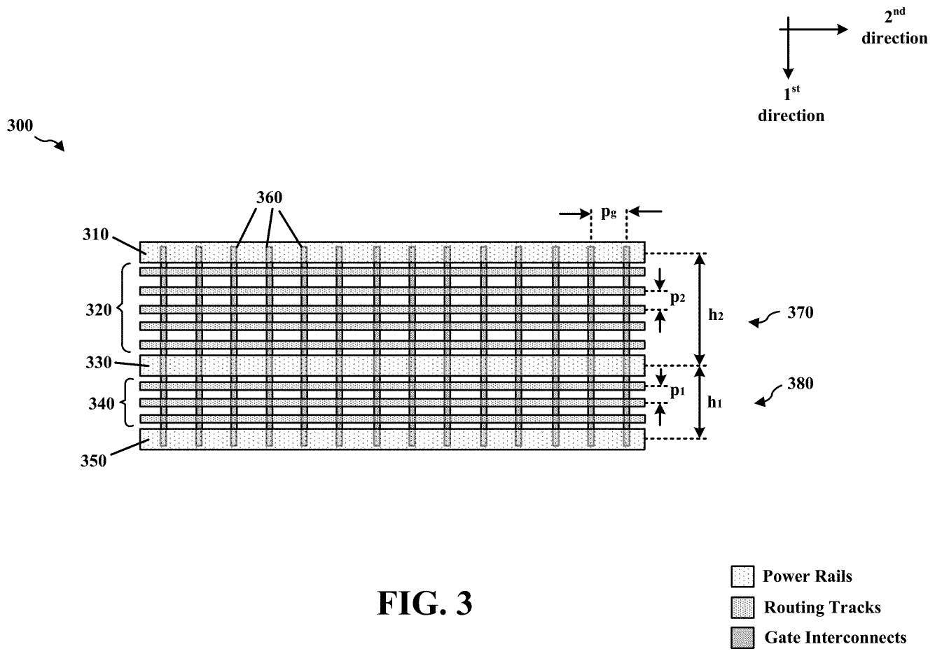

FIG. 3 is a first diagram 300 conceptually illustrating a top view of a heterogeneous height logic cell architecture. As illustrated in FIG. 3, the heterogeneous height logic cell architecture may include a mixed height architecture, where a taller height portion 370 with height h₂ is located adjacent a shorter height portion 380 with height h₁, where h₂>h₁ and a power rail 330 is shared between the two portions. A height ratio h_{R}=h₂/h₁ between the two heights may be a non-integer value in a first configuration or an integer value (e.g., 2, 3) in a second configuration. The power rail 330 may provide a power supply voltage Vdd or a ground voltage Vss to both the taller height portion 370 and the shorter height portion 380. The taller height portion 370 includes power rails 310, 330 that extend in the second direction and gate interconnects 360 that extend in the first direction, which is orthogonal to the second direction. The taller height portion 370 provides for a set of Mₓ layer tracks 320 that extend unidirectionally in the second direction between the power rails 310, 330. The Mₓ layer may be a lowest metal layer that extends unidirectionally in the second direction. For example, the Mₓ layer may be an M1 metal layer or an M0 metal layer. The Mₓ layer tracks 320 may be used for intra-cell routing. The shorter height portion 380 includes power rails 330, 350 that extend in the second direction and the gate interconnects 360. The shorter height portion 380 provides for a set of Mₓ layer tracks 340 that extend unidirectionally in the second direction between the power rails 330, 350. The Mₓ layer tracks 340 may also be used for intra-cell routing.

The gate interconnects 360 have the same pitch p_{g} for both the taller height portion 370 and the shorter height portion 380, where the pitch p_{g} is the distance between the centers of adjacent gate interconnects. The pitch p₂ of the set of Mₓ layer tracks 320 may be the same or different than the pitch p₁ of the set of Mₓ layer tracks 340, where the pitches p₁, p₂ are the distances between the centers of corresponding adjacent Mₓ layer tracks. In a first configuration, the set of Mₓ layer tracks 320 and the set of Mₓ layer tracks 340 have the same pitch (p₂=p₁). In a second configuration, the set of Mₓ layer tracks 320 and the set of Mₓ layer tracks 340 have different pitches (p₂≠p₁).

The taller height portion 370 may be utilized for complex logic cells (e.g., flip-flops or other complex or higher performance logic), as the taller height portion 370 provides a sufficient number of Mₓ layer tracks 320 for intra-cell routing of the complex logic cells. The taller height portion 370 also provides for a larger area (i.e., greater number of fins) for the p-type and n-type diffusion regions, and therefore may provide higher performance than the shorter height portion 380. The shorter height portion 380 may be utilized for simple logic cells (e.g., combinational logic cells), as less Mₓ layer tracks 340 are provided.

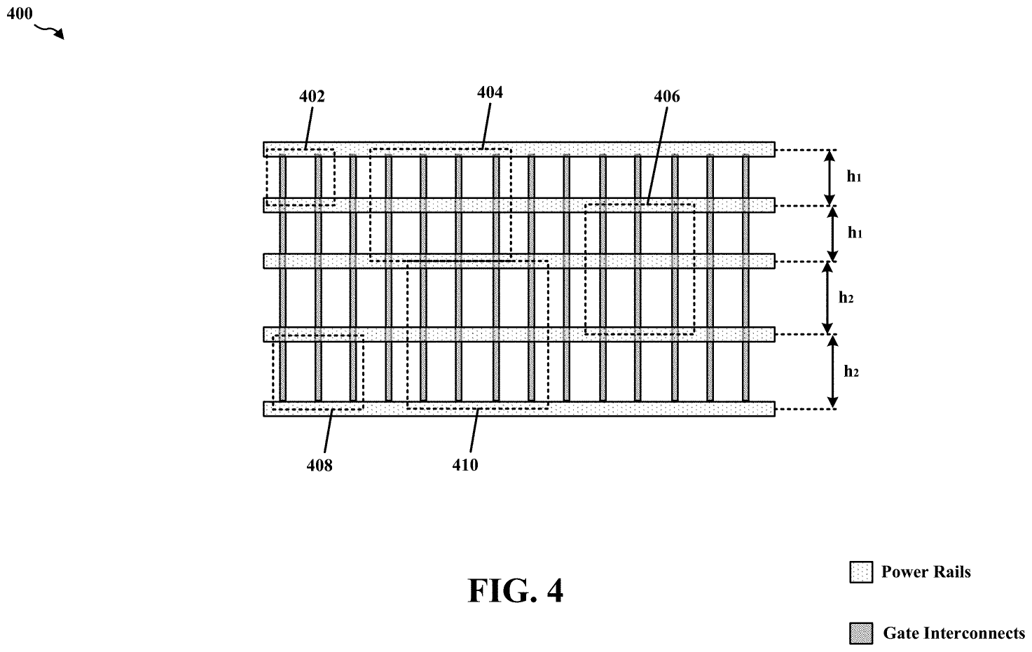

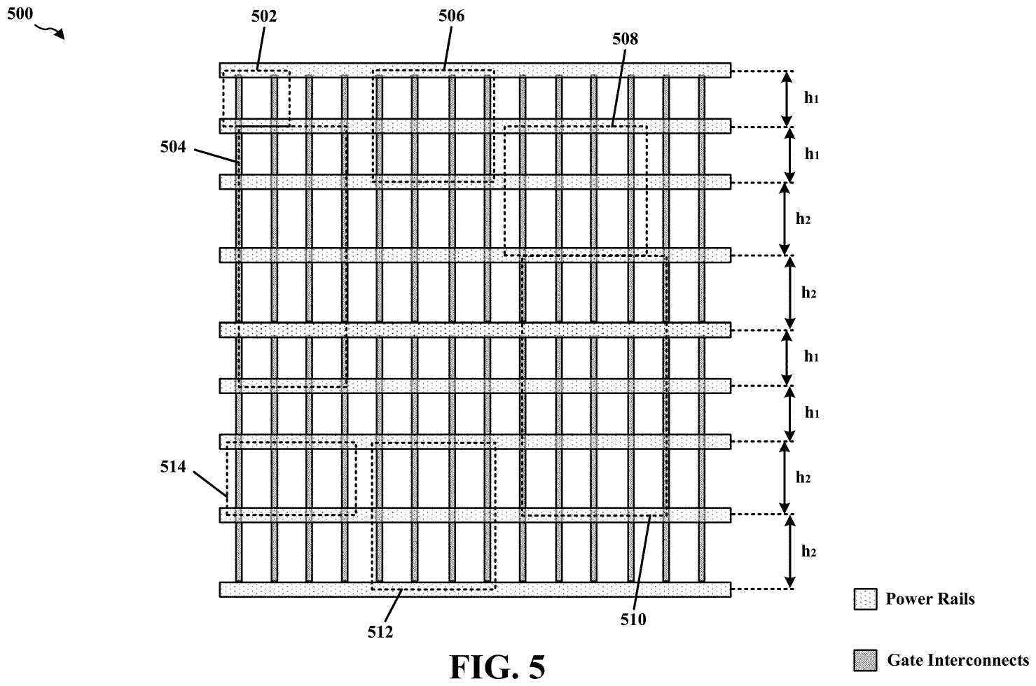

Within the taller height portion 370 and the shorter height portion 380, logic cells may be located. A logic cell may span just one of the portions 370, 380 or across both portions 370, 380. Referring again to the height ratio h_{R}=h₂/h₁, the height ratio h_{R}=h₂/h₁ may be a non-integer value or an integer value. If the height ratio h_{R}=h₂/h₁ is a non-integer value, individual logic cells may span one of the portions 370, 380 and/or across both portions 370, 380. Accordingly, individual logic cells of an IC may have a homogeneous-height design and/or a heterogeneous-height design. If the height ratio h_{R}=h₂/h₁ is an integer value, two configurations are possible. In a first configuration, individual logic cells may span both portions 370, 380. Accordingly, all individual logic cells of an IC may have a heterogeneous-height design. In a second configuration, individual logic cells may span one of the portions 370, 380 and/or both portions 370, 380. Accordingly, individual logic cells of an IC may have a homogeneous-height design and/or a heterogeneous-height design. Example locations of logic cells within the heterogeneous height logic cell architecture are illustrated in FIGS. 4, 5.

FIG. 4 is a second diagram 400 conceptually illustrating a top view of the heterogeneous height logic cell architecture. As illustrated in FIG. 4, the logic cell 402 may be a short single-height cell with height h₁, the logic cell 404 may be a short double-height cell with height 2*h₁, the logic cell 408 may be a tall single-height cell with height h₂, the logic cell 410 may be a tall double-height cell with height 2*h₂, and the logic cell 406 may span both the tall and short height portions with height h₁+h₂. In one example, the logic cells 402, 404 may be simple logic cells; the logic cells 408, 410 may be complex logic cells; and the logic cell 406 may have mixed simple/complex functionality.

FIG. 5 is a third diagram 500 conceptually illustrating a top view of the heterogeneous height logic cell architecture. As illustrated in FIG. 5, the logic cell 502 may be a short single-height cell with height h₁, the logic cell 506 may be a short double-height cell with height 2*h₁, the logic cell 514 may be a tall single-height cell with height h₂, the logic cell 512 may be a tall double-height cell with height 2*h₂, and the logic cells 504, 508, 510 may include both tall and short height portions. For example, the logic cell 504 may include short, tall, tall, short portions, in that order, with height 2*h₁+2*h₂; the logic cell 508 may include short and tall portions with height h₁+h₂; and the logic cell 510 may include tall, short, short, tall portions, in that order, with height 2*h₁+2*h₂. In one example, the logic cells 502, 506 may be simple logic cells; the logic cells 512, 514 may be complex logic cells; and the logic cells 504, 508, 510 may have mixed simple/complex functionality.

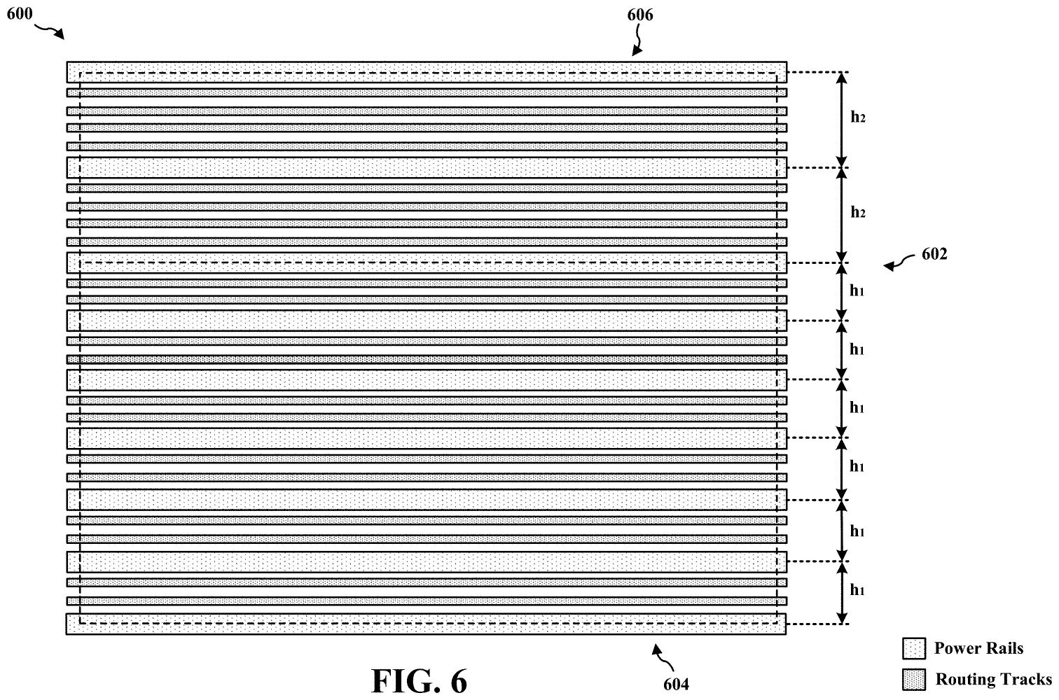

FIG. 6 is a fourth diagram 600 conceptually illustrating a top view of the heterogeneous height logic cell architecture. The heterogeneous height logic cell architecture may include shorter height portions with a first height h₁ and taller height portions with a second height h₂, where h₂>h₁, and where the taller height portions have a greater number of Mₓ layer tracks than the shorter height portions. One logic cell 602 may include both taller height portions and shorter height portions. For example, the logic cell 602 may include a first set of transistor logic 604 and a second set of transistor logic 606. The transistor logic includes both p-type MOS (pMOS) and n-type MOS (nMOS) transistors forming logic gates within the corresponding taller-height/shorter-height portions. A height hₘ of the one logic cell 602 is equal to (n₁−1)h₁+(n₂−1)h₂, where n₁≥2 and is a number of power rail tracks within the first set of transistor logic, and n₂≥2 and is a number of power rail tracks within the second set of transistor logic, and where n₁+n₂−1 is a total number of power rails within the one logic cell 602. As illustrated in FIG. 6, n₁=7 and n₂=3, and therefore the height of the logic cell 602 is 6*h₁+2*h₂.

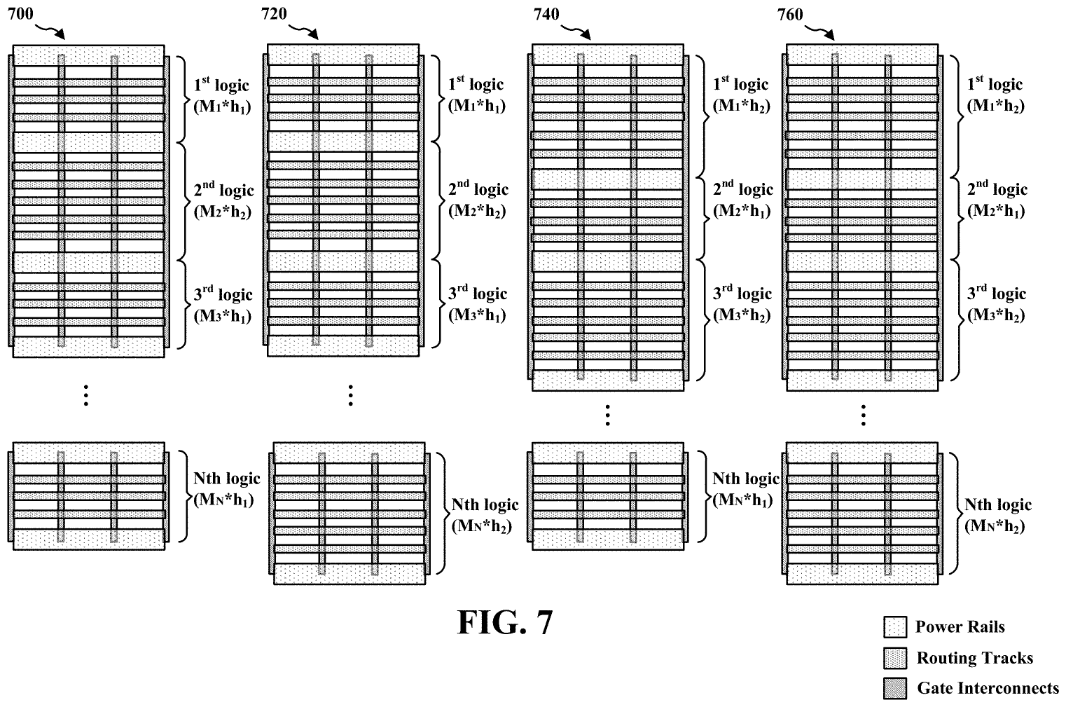

FIG. 7 are a set of diagrams 700, 720, 740, 760 conceptually illustrating top views of different configurations of the heterogeneous height logic cell architecture. Each set of transistor logic is illustrated by a single-height cell that represents a set of Mₛ cells, where s is the particular set and the set of transistor logic has height Mₛ*h. For example, in the diagram 700, a first set of transistor logic with the smaller height architecture includes n₁=M₁+1 power rails, and has height M₁*h₁, and correspondingly, a height of (n₁−1)h₁. Adjacent the first set of transistor logic is a second set of transistor logic with the taller height architecture. The second set of transistor logic includes n₂=M₂+1 power rails, and has height M₂*h₂, and correspondingly, a height of (n₂−1)h₂. Adjacent the second set of transistor logic is a third set of transistor logic with the smaller height architecture. The third set of transistor logic includes n₃=M₃+1 power rails, and has height M₃*h₁, and correspondingly, a height of (n₃−1)h₁. Adjacent the third set of transistor logic are different sets of different taller and smaller height architectures, leading finally to an N^{th} set of transistor logic with the smaller height architecture. The N^{th} set of transistor logic includes n_{N}=M_{N}+1 power rails, and has height M_{N}*h₁, and correspondingly, a height of (n_{N}−1)h₁.

For another example, in the diagram 720, a first set of transistor logic with the smaller height architecture includes n₁=M₁+1 power rails, and has height M₁*h₁, and correspondingly, a height of (n₁−1)h₁. Adjacent the first set of transistor logic is a second set of transistor logic with the taller height architecture. The second set of transistor logic includes n₂=M₂+1 power rails, and has height M₂*h₂, and correspondingly, a height of (n₂−1)h₂. Adjacent the second set of transistor logic is a third set of transistor logic with the smaller height architecture. The third set of transistor logic includes n₃=M₃+1 power rails, and has height M₃*h₁, and correspondingly, a height of (n₃−1)h₁. Adjacent the third set of transistor logic are different sets of different taller and smaller height architectures, leading finally to an N^{th} set of transistor logic with the taller height architecture. The N^{th} set of transistor logic includes n_{N}=M_{N}+1 power rails, and has height M_{N}*h₂, and correspondingly, a height of (n_{N}−1)h₂.

For another example, in the diagram 740, a first set of transistor logic with the taller height architecture includes n₁=M₁+1 power rails, and has height M₁*h₂, and correspondingly, a height of (n₁−1)h₂. Adjacent the first set of transistor logic is a second set of transistor logic with the shorter height architecture. The second set of transistor logic includes n₂=M₂+1 power rails, and has height M₂*h₁, and correspondingly, a height of (n₂−1)h₁. Adjacent the second set of transistor logic is a third set of transistor logic with the taller height architecture. The third set of transistor logic includes n₃=M₃+1 power rails, and has height M₃*h₂, and correspondingly, a height of (n₃−1)h₂. Adjacent the third set of transistor logic are different sets of different taller and smaller height architectures, leading finally to an N^{th} set of transistor logic with the smaller height architecture. The N^{th} set of transistor logic includes n_{N}=M_{N}+1 power rails, and has height M_{N}*h₁, and correspondingly, a height of (n_{N}−1)h₁.

For another example, in the diagram 760, a first set of transistor logic with the taller height architecture includes n₁=M₁+1 power rails, and has height M₁*h₂, and correspondingly, a height of (n₁−1)h₂. Adjacent the first set of transistor logic is a second set of transistor logic with the shorter height architecture. The second set of transistor logic includes n₂=M₂+1 power rails, and has height M₂*h₁, and correspondingly, a height of (n₂−1)h₁. Adjacent the second set of transistor logic is a third set of transistor logic with the taller height architecture. The third set of transistor logic includes n₃=M₃+1 power rails, and has height M₃*h₂, and correspondingly, a height of (n₃−1)h₂. Adjacent the third set of transistor logic are different sets of different taller and smaller height architectures, leading finally to an N^{th} set of transistor logic with the taller height architecture. The N^{th} set of transistor logic includes n_{N}=M_{N}+1 power rails, and has height M_{N}*h₂, and correspondingly, a height of (n_{N}−1)h₂.

Generally, one logic cell may include any combination of sets of logic cells as illustrated in the diagrams 700, 720, 740, 760. For example, if one logic cell includes first, second, and third sets of transistor logic, with combination short-tall-short architectures, a height hₘ of the one logic cell would be equal to (n₁−1)h₁+(n₂−1)h₂+(n₃−1)h₁, where n₁≥2 and is a number of power rail tracks within the first set of transistor logic, n₂≥2 and is a number of power rail tracks within the second set of transistor logic, and n₃≥2 and is a number of power rail tracks within the third set of transistor logic, and where n₁+n₂+n₃−2 is a total number of power rails within the one logic cell. Further, in another example, if one logic cell includes first, second, and third sets of transistor logic, with combination tall-short-tall architectures, a height hₘ of the one logic cell would be equal to (n₁−1)h₂+(n₂−1)h₁+(n₃−1)h₂, where n₁≥2 and is a number of power rail tracks within the first set of transistor logic, n₂≥2 and is a number of power rail tracks within the second set of transistor logic, and n₃≥2 and is a number of power rail tracks within the third set of transistor logic, and where n₁+n₂+n₃−2 is a total number of power rails within the one logic cell.

Referring again to FIGS. 3-7, a MOS IC includes a first set of transistor logic 380. The first set of transistor logic 380 has a first plurality of gate interconnects 360 extending in a first direction. The first plurality of gate interconnects 360 has a gate pitch p_{g}. The first set of transistor logic 380 has one or more pairs of power rails 330, 350 providing a power supply voltage and a ground voltage to logic between each corresponding pair of power rails 330, 350. The first set of transistor logic 380 has a first cell height h₁ and has a first number of Mₓ layer tracks 340 that extend unidirectionally in a second direction between each pair of power rails 330, 350. The second direction is orthogonal to the first direction. The MOS IC further includes a second set of transistor logic 370. The second set of transistor logic 370 is located adjacent in the first direction to the first set of transistor logic 380. The second set of transistor logic 370 has a second plurality of gate interconnects 360 extending in the first direction. The second plurality of gate interconnects 360 has the same gate pitch p_{g} as the first plurality of gate interconnects 360 and each is collinear with a respective one of the first plurality of gate interconnects 360. Two gate interconnects may be said to be “collinear” if they lie along the same straight line. The second set of transistor logic 370 has one or more pairs of power rails 310, 330 providing the power supply voltage and the ground voltage to logic between each corresponding pair of power rails 310, 330. The second set of transistor logic 370 has a second cell height h₂ and has a second number of Mₓ layer tracks 320 that extend unidirectionally in the second direction between each pair of power rails 310, 330. The second cell height h₂ is greater than the first cell height h₁. The second number of Mₓ layer tracks 320 is greater than the first number of Mₓ layer tracks 340. At least one of (1) a height ratio h_{R}=h₂/h₁ is a non-integer value and a subset of the first set of transistor logic and a subset of the second set of transistor logic may or may not be within one logic cell, or (2) the height ratio h_{R}=h₂/h₁ is an integer value and a subset of the first set of transistor logic and a subset of the second set of transistor logic are within one logic cell.

In one configuration, a power rail 330 of the one or more pairs of power rails 350, 330, 310 of the first and second sets of transistor logic 380, 370 extends in the second direction between the first set of transistor logic 380 and the second set of transistor logic 370. The power rail 330 is a shared power rail and is configured to provide one of the power supply voltage or the ground voltage to at least a subset of the first set of transistor logic 380 and to at least a subset of the second set of transistor logic 370.

In one configuration, a pitch p₁ of the first number of Mₓ layer tracks 340 of the first set of transistor logic 380, and a pitch p₂ of the second number of Mₓ layer tracks 320 of the second set of transistor logic 370 are the same. In another configuration, p₁≠p₂.

In one configuration, the Mₓ layer is a lowest metal layer that extends unidirectionally in the second direction. For example, the Mₓ layer may be an M0 layer or an M1 layer.

In one configuration, the height ratio h_{R}=h₂/h₁ is a non-integer value, and the first set of transistor logic 380 includes a first set of logic cells, and the second set of transistor logic 370 includes a second set of logic cells (for example, see logic cells 402, 404, 408, 410 of FIG. 4; see also logic cells 502, 506, 512, 514 of FIG. 5). Alternatively, the first and second sets of transistor logic 370, 380 or subsets of the first and second sets of transistor logic 370, 380 may be within the same logic cell (for example, see logic cell 406 of FIG. 4; see also logic cells 504, 508 of FIG. 5). In such a configuration, the height ratio h_{R}=h₂/h₁ may or may not be a non-integer value.

In one configuration, the subset of the first set of transistor logic 380, 604 and the subset of the second set of transistor logic 370, 606 are within one logic cell 602 (for example, see FIG. 6; see also logic cell 406 of FIG. 4 and logic cells 504, 508 of FIG. 5). A height hₘ of the one logic cell 602 is equal to (n₁−1)h₁+(n₂−1)h₂, where n₁≥2 and is a number of power rail tracks within the subset of the first set of transistor logic 604, and n₂≥2 and is a number of power rail tracks within the subset of the second set of transistor logic 606, and where n₁+n₂−1 is a total number of power rails within the one logic cell 602. In one configuration, the subset of the first set of transistor logic 380, 604 and the subset of the second set of transistor logic 370, 606 are coupled together within the one logic cell 602. That is, the first set of transistor logic 380, 604 and the second set of transistor logic 370, 606 may be uncoupled from each other or coupled together within the one logic cell 602. When the first set of transistor logic 380, 604 and the second set of transistor logic 370, 606 are uncoupled from each other, the one logic cell 602 may have separate inputs and separate outputs for the first set of transistor logic 380, 604 and the second set of transistor logic 370, 606. When the first set of transistor logic 380, 604 and the second set of transistor logic 370, 606 are coupled to each other, the one logic cell 602 may have joint inputs and joint outputs for the first set of transistor logic 380, 604 and the second set of transistor logic 370, 606.

In one configuration, for a short-tall-short architecture (see for example, diagrams 700, 720 of FIG. 7), the MOS IC may further include a third set of transistor logic. The third set of transistor logic has a third plurality of gate interconnects extending in the first direction. The third plurality of gate interconnects has the same gate pitch as the first plurality of gate interconnects and the second plurality of gate interconnects, and each is collinear with respective ones of the first plurality of gate interconnects and the second plurality of gate interconnects. The third set of transistor logic has one or more pairs of power rails providing the power supply voltage and the ground voltage to logic between each corresponding pair of power rails. The third set of transistor logic has the first cell height h₁ and has the first number of Mₓ layer tracks that extend unidirectionally in the second direction between each pair of power rails.

The second set of transistor logic is between the first set of transistor logic and the third set of transistor logic. In one configuration, a power rail of the one or more pairs of power rails of the second and third sets of transistor logic extends in the second direction between the second set of transistor logic and the third set of transistor logic. The power rail is a shared power rail and is configured to provide one of the power supply voltage or the ground voltage to at least a subset of the second set of transistor logic and to at least a subset of the third set of transistor logic. In one configuration, a subset of the first set of transistor logic, a subset of the second set of transistor logic, and a subset of the third set of transistor logic are within one logic cell. A height hₘ of the one logic cell is equal to (n₁−1)h₁+(n₂−1)h₂+(n₃−1)h₁, where n₁≥2 and is a number of power rail tracks within the subset of the first set of transistor logic, n₂≥2 and is a number of power rail tracks within the subset of the second set of transistor logic, and n₃≥2 and is a number of power rail tracks within the subset of the third set of transistor logic, and where n₁+n₂+n₃−2 is a total number of power rails within the one logic cell. In one configuration, the subset of the first set of transistor logic, the subset of the second set of transistor logic, and the subset of the third set of transistor logic are coupled together within the one logic cell.

In one configuration, for a tall-short-tall architecture (see for example, diagrams 740, 760 of FIG. 7), the MOS IC may further include a third set of transistor logic. The third set of transistor logic has a third plurality of gate interconnects extending in the first direction. The third plurality of gate interconnects has the same gate pitch as the first plurality of gate interconnects and the second plurality of gate interconnects, and each is collinear with respective ones of the first plurality of gate interconnects and the second plurality of gate interconnects. The third set of transistor logic has one or more pairs of power rails providing the power supply voltage and the ground voltage to logic between each corresponding pair of power rails. The third set of transistor logic has the second cell height h₂ and has the second number of Mₓ layer tracks that extend unidirectionally in the second direction between each pair of power rails. The first set of transistor logic is between the second set of transistor logic and the third set of transistor logic. In one configuration, a power rail of the one or more pairs of power rails of the first and third sets of transistor logic extends in the second direction between the first set of transistor logic and the third set of transistor logic. The power rail is a shared power rail providing one of the power supply voltage or the ground voltage to at least a subset of the first set of transistor logic and to at least a subset of the third set of transistor logic. In one configuration, a subset of the first set of transistor logic, a subset of the second set of transistor logic, and a subset of the third set of transistor logic are within one logic cell. A height hₘ of the one logic cell is equal to (n₃−1)h₂+(n₁−1)h₁+(n₂−1)h₂, where n₁≥2 and is a number of power rail tracks within the subset of the first set of transistor logic, n₂≥2 and is a number of power rail tracks within the subset of the second set of transistor logic, and n₃≥2 and is a number of power rail tracks within the subset of the third set of transistor logic, and where n₁+n₂+n₃−2 is a total number of power rails within the one logic cell. In one configuration, the subset of the first set of transistor logic, the subset of the second set of transistor logic, and the subset of the third set of transistor logic are coupled together within the one logic cell.

Referring to FIG. 7, diagrams 700, 720, 740, 760, in one configuration, the MOS IC includes n sets of transistor logic. The n sets of transistor logic are located adjacent in the first direction to one of the first set of transistor logic or the second set of transistor logic. Each set of the n sets of transistor logic has a same number of gate interconnects extending in the first direction. The gate interconnects have the same gate pitch and each is collinear with respective ones of the first and second plurality of gate interconnects. Each set of then sets of transistor logic has one or more pairs of power rails providing the power supply voltage and the ground voltage to transistor logic between each corresponding pair of power rails. Each set of the n sets of transistor logic has either the first cell height h₁ and the first number of Mₓ layer tracks or the second cell height h₂ and the second number of Mₓ layer tracks.

As discussed supra, for the provided heterogeneous height logic cell architecture, relatively taller and relatively shorter logic architectures may be located adjacent to each other, both with aligned gate interconnects with the same pitch. The taller logic architecture may provide a greater number of routing tracks than the shorter logic architecture. The taller logic architecture may provide relatively higher performance with a lower area efficiency, whereas the shorter logic architecture may provide relatively lower performance with a higher area efficiency. Logic cells may be located within the taller logic architecture, the shorter logic architecture, or within both the taller and shorter logic architectures. The heterogeneous height logic cell architecture may allow for optimized area/performance, while also allowing for easier process scaling to smaller technology process nodes.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

The following examples are illustrative only and may be combined with aspects of other embodiments or teachings described herein, without limitation.

Example 1 is a MOS IC including a first set of transistor logic. The first set of transistor logic has a first plurality of gate interconnects extending in a first direction. The first plurality of gate interconnects has a gate pitch. The first set of transistor logic has one or more pairs of power rails providing a power supply voltage and a ground voltage to logic between each corresponding pair of power rails. The first set of transistor logic has a first cell height h₁ and has a first number of Mₓ layer tracks that extend unidirectionally in a second direction between each pair of power rails. The second direction is orthogonal to the first direction. The MOS IC further includes a second set of transistor logic. The second set of transistor logic is located adjacent in the first direction to the first set of transistor logic. The second set of transistor logic has a second plurality of gate interconnects extending in the first direction. The second plurality of gate interconnects has a same gate pitch as the first plurality of gate interconnects and each is collinear with a respective one of the first plurality of gate interconnects. The second set of transistor logic has one or more pairs of power rails providing the power supply voltage and the ground voltage to logic between each corresponding pair of power rails. The second set of transistor logic has a second cell height h₂ and has a second number of Mₓ layer tracks that extend unidirectionally in the second direction between each pair of power rails. The second cell height h₂ is greater than the first cell height h₁. The second number of Mₓ layer tracks is greater than the first number of Mₓ layer tracks. At least one of a height ratio h_{R}=h₂/h₁ is a non-integer value or a subset of the first set of transistor logic and a subset of the second set of transistor logic are within one logic cell.

Example 2 is the MOS IC of example 1, wherein a power rail of the one or more pairs of power rails of the first and second sets of transistor logic extends in the second direction between the first set of transistor logic and the second set of transistor logic. The power rail is configured to provide one of the power supply voltage or the ground voltage to at least a subset of the first set of transistor logic and to at least a subset of the second set of transistor logic.

Example 3 is the MOS IC of any of examples 1 and 2, wherein a pitch of the first number of Mₓ layer tracks of the first set of transistor logic, and a pitch of the second number of Mₓ layer tracks of the second set of transistor logic are the same.

Example 4 is the MOS IC of any of examples 1 to 3, wherein the Mₓ layer is a lowest metal layer that extends unidirectionally in the second direction.

Example 5 is the MOS IC of any of examples 1 to 4, wherein the height ratio h_{R}=h₂/h₁ is a non-integer value, and the first set of transistor logic includes a first set of logic cells, and the second set of transistor logic includes a second set of logic cells.

Example 6 is the MOS IC of any of examples 1 to 5, wherein the subset of the first set of transistor logic and the subset of the second set of transistor logic are within one logic cell. A height hₘ of the one logic cell is equal to (n₁−1)h₁+(n₂−1)h₂, where n₁≥2 and is a number of power rail tracks within the subset of the first set of transistor logic, and n₂≥2 and is a number of power rail tracks within the subset of the second set of transistor logic, and where n₁+n₂−1 is a total number of power rails within the one logic cell.

Example 7 is the MOS IC of example 6, wherein the subset of the first set of transistor logic and the subset of the second set of transistor logic are coupled together within the one logic cell.

Example 8 is the MOS IC of any of examples 1 to 7, further including a third set of transistor logic. The third set of transistor logic has a third plurality of gate interconnects extending in the first direction. The third plurality of gate interconnects has the same gate pitch as the first plurality of gate interconnects and the second plurality of gate interconnects, and each is collinear with respective ones of the first plurality of gate interconnects and the second plurality of gate interconnects. The third set of transistor logic has one or more pairs of power rails providing the power supply voltage and the ground voltage to logic between each corresponding pair of power rails. The third set of transistor logic has the first cell height h₁ and has the first number of Mₓ layer tracks that extend unidirectionally in the second direction between each pair of power rails. The second set of transistor logic is between the first set of transistor logic and the third set of transistor logic.

Example 9 is the MOS IC of example 8, wherein a power rail of the one or more pairs of power rails of the second and third sets of transistor logic extends in the second direction between the second set of transistor logic and the third set of transistor logic. The power rail is configured to provide one of the power supply voltage or the ground voltage to at least a subset of the second set of transistor logic and to at least a subset of the third set of transistor logic.

Example 10 is the MOS IC of any of examples 8 and 9, wherein a subset of the first set of transistor logic, a subset of the second set of transistor logic, and a subset of the third set of transistor logic are within one logic cell. A height hₘ of the one logic cell is equal to (n₁−1)h₁+(n₂−1)h₂+(n₃−1)h₁, where n₁≥2 and is a number of power rail tracks within the subset of the first set of transistor logic, n₂≥2 and is a number of power rail tracks within the subset of the second set of transistor logic, and n₃≥2 and is a number of power rail tracks within the subset of the third set of transistor logic, and where n₁+n₂+n₃−2 is a total number of power rails within the one logic cell.

Example 11 is the MOS IC of example 10, wherein the subset of the first set of transistor logic, the subset of the second set of transistor logic, and the subset of the third set of transistor logic are coupled together within the one logic cell.

Example 12 is the MOS IC of any of examples 1 to 11, further including a third set of transistor logic. The third set of transistor logic has a third plurality of gate interconnects extending in the first direction. The third plurality of gate interconnects has the same gate pitch as the first plurality of gate interconnects and the second plurality of gate interconnects, and each is collinear with respective ones of the first plurality of gate interconnects and the second plurality of gate interconnects. The third set of transistor logic has one or more pairs of power rails providing the power supply voltage and the ground voltage to logic between each corresponding pair of power rails. The third set of transistor logic has the second cell height h₂ and has the second number of Mₓ layer tracks that extend unidirectionally in the second direction between each pair of power rails. The first set of transistor logic is between the second set of transistor logic and the third set of transistor logic.

Example 13 is the MOS IC of example 12, wherein a power rail of the one or more pairs of power rails of the first and third sets of transistor logic extends in the second direction between the first set of transistor logic and the third set of transistor logic. The power rail is configured to provide one of the power supply voltage or the ground voltage to at least a subset of the first set of transistor logic and to at least a subset of the third set of transistor logic.

Example 14 is the MOS IC of any of examples 12 and 13, wherein a subset of the first set of transistor logic, a subset of the second set of transistor logic, and a subset of the third set of transistor logic are within one logic cell. A height hₘ of the one logic cell is equal to (n₃−1)h₂+(n₁−1)h₁+(n₂−1)h₂, where n₁≥2 and is a number of power rail tracks within the subset of the first set of transistor logic, n₂≥2 and is a number of power rail tracks within the subset of the second set of transistor logic, and n₃≥2 and is a number of power rail tracks within the subset of the third set of transistor logic, and where n₁+n₂+n₃−2 is a total number of power rails within the one logic cell.

Example 15 is the MOS IC of example 14, wherein the subset of the first set of transistor logic, the subset of the second set of transistor logic, and the subset of the third set of transistor logic are coupled together within the one logic cell.

Example 16 is the MOS IC of any of examples 1 to 15, further including n sets of transistor logic. The n sets of transistor logic are located adjacent in the first direction to one of the first set of transistor logic or the second set of transistor logic. Each set of the n sets of transistor logic has a same number of gate interconnects extending in the first direction. The gate interconnects have the same gate pitch and each is collinear with respective ones of the first and second plurality of gate interconnects. Each set of then sets of transistor logic has one or more pairs of power rails providing the power supply voltage and the ground voltage to logic between each corresponding pair of power rails. Each set of the n sets of transistor logic has either the first cell height h₁ and the first number of Mₓ layer tracks or the second cell height h₂ and the second number of Mₓ layer tracks.

What is claimed is:

1. A metal oxide semiconductor (MOS) integrated circuit (IC), comprising:
a first set of transistor logic having a first plurality of gate interconnects extending in a first direction, the first plurality of gate interconnects having a gate pitch, the first set of transistor logic having one or more pairs of power rails providing a power supply voltage and a ground voltage to logic between each corresponding pair of power rails, the first set of transistor logic having a first cell height h₁ and having a first number of metal x (Mₓ) layer tracks that extend unidirectionally in a second direction between each pair of power rails, the second direction being orthogonal to the first direction; and
a second set of transistor logic located adjacent in the first direction to the first set of transistor logic, the second set of transistor logic having a second plurality of gate interconnects extending in the first direction, the second plurality of gate interconnects having a same gate pitch as the first plurality of gate interconnects and each being collinear with a respective one of the first plurality of gate interconnects, the second set of transistor logic having one or more pairs of power rails providing the power supply voltage and the ground voltage to logic between each corresponding pair of power rails, the second set of transistor logic having a second cell height h₂ and having a second number of Mₓ layer tracks that extend unidirectionally in the second direction between each pair of power rails, the second cell height h₂ being greater than the first cell height h₁, the second number of Mₓ layer tracks being greater than the first number of Mₓ layer tracks,
wherein at least one of a height ratio h_{R}=h₂/h₁ is a non-integer value or a subset of the first set of transistor logic and a subset of the second set of transistor logic are within one logic cell.

2. The MOS IC of claim 1, wherein a power rail of the one or more pairs of power rails of the first and second sets of transistor logic extends in the second direction between the first set of transistor logic and the second set of transistor logic, the power rail being configured to provide one of the power supply voltage or the ground voltage to at least a subset of the first set of transistor logic and to at least a subset of the second set of transistor logic.

3. The MOS IC of claim 1, wherein a pitch of the first number of Mₓ layer tracks of the first set of transistor logic, and a pitch of the second number of Mₓ layer tracks of the second set of transistor logic are the same.

4. The MOS IC of claim 1, wherein the Mₓ layer is a lowest metal layer that extends unidirectionally in the second direction.

5. The MOS IC of claim 1, wherein the height ratio h_{R}=h₂/h₁ is a non-integer value, and the first set of transistor logic comprises a first set of logic cells, and the second set of transistor logic comprises a second set of logic cells.

6. The MOS IC of claim 1, wherein the subset of the first set of transistor logic and the subset of the second set of transistor logic are within one logic cell, a height hₘ of the one logic cell being equal to (n₁−1)h₁+(n₂−1)h₂, where n₁≥2 and is a number of power rail tracks within the subset of the first set of transistor logic, and n_{z}≥2 and is a number of power rail tracks within the subset of the second set of transistor logic, and where n₁+n₂−1 is a total number of power rails within the one logic cell.

7. The MOS IC of claim 6, wherein the subset of the first set of transistor logic and the subset of the second set of transistor logic are coupled together within the one logic cell.

8. The MOS IC of claim 1, further comprising:
a third set of transistor logic having a third plurality of gate interconnects extending in the first direction, the third plurality of gate interconnects having the same gate pitch and each being collinear with respective ones of the first plurality of gate interconnects and the second plurality of gate interconnects, the third set of transistor logic having one or more pairs of power rails providing the power supply voltage and the ground voltage to logic between each corresponding pair of power rails, the third set of transistor logic having the first cell height h₁ and having the first number of Mₓ layer tracks that extend unidirectionally in the second direction between each pair of power rails, the second set of transistor logic being between the first set of transistor logic and the third set of transistor logic.

9. The MOS IC of claim 8, wherein a power rail of the one or more pairs of power rails of the second and third sets of transistor logic extends in the second direction between the second set of transistor logic and the third set of transistor logic, the power rail being configured to provide one of the power supply voltage or the ground voltage to at least a subset of the second set of transistor logic and to at least a subset of the third set of transistor logic.

10. The MOS IC of claim 8, wherein a subset of the first set of transistor logic, a subset of the second set of transistor logic, and a subset of the third set of transistor logic are within one logic cell, a height hₘ of the one logic cell being equal to (n₁−1)h₁+(n₂−1)h₂+(n₃−1)h₁, where n₁≥2 and is a number of power rail tracks within the subset of the first set of transistor logic, n₂≥2 and is a number of power rail tracks within the subset of the second set of transistor logic, and n₃≥2 and is a number of power rail tracks within the subset of the third set of transistor logic, and where n₁+n₂+n₃−2 is a total number of power rails within the one logic cell.

11. The MOS IC of claim 10, wherein the subset of the first set of transistor logic, the subset of the second set of transistor logic, and the subset of the third set of transistor logic are coupled together within the one logic cell.

12. The MOS IC of claim 1, further comprising:
a third set of transistor logic having a third plurality of gate interconnects extending in the first direction, the third plurality of gate interconnects having the same gate pitch and each being collinear with respective ones of the first plurality of gate interconnects and the second plurality of gate interconnects, the third set of transistor logic having one or more pairs of power rails providing the power supply voltage and the ground voltage to logic between each corresponding pair of power rails, the third set of transistor logic having the second cell height h₂ and having the second number of Mₓ layer tracks that extend unidirectionally in the second direction between each pair of power rails, the first set of transistor logic being between the second set of transistor logic and the third set of transistor logic.

13. The MOS IC of claim 12, wherein a power rail of the one or more pairs of power rails of the first and third sets of transistor logic extends in the second direction between the first set of transistor logic and the third set of transistor logic, the power rail configured to provide one of the power supply voltage or the ground voltage to at least a subset of the first set of transistor logic and to at least a subset of the third set of transistor logic.

14. The MOS IC of claim 12, wherein a subset of the first set of transistor logic, a subset of the second set of transistor logic, and a subset of the third set of transistor logic are within one logic cell, a height hₘ of the one logic cell being equal to (n₃−1)h₂+(n₁−1)h₁+(n₂−1)h₂, where n₁≥2 and is a number of power rail tracks within the subset of the first set of transistor logic, n₂≥2 and is a number of power rail tracks within the subset of the second set of transistor logic, and n₃≥2 and is a number of power rail tracks within the subset of the third set of transistor logic, and where n₁+n₂+n₃−2 is a total number of power rails within the one logic cell.

15. The MOS IC of claim 14, wherein the subset of the first set of transistor logic, the subset of the second set of transistor logic, and the subset of the third set of transistor logic are coupled together within the one logic cell.

16. The MOS IC of claim 1, further comprising:
n sets of transistor logic located adjacent in the first direction to one of the first set of transistor logic or the second set of transistor logic, each set of the n sets of transistor logic having a same number of gate interconnects extending in the first direction, the gate interconnects having the same gate pitch and each being collinear with respective ones of the first and second plurality of gate interconnects, each set of then sets of transistor logic having one or more pairs of power rails providing the power supply voltage and the ground voltage to logic between each corresponding pair of power rails, each set of the n sets of transistor logic having either the first cell height h₁ and the first number of Mₓ layer tracks or the second cell height h₂ and the second number of Mₓ layer tracks.
